(19) United States
(12) Patent Application Publication
(10) Pub. No.: US 2025/0054783 A1
(43) Pub. Date: Feb. 13, 2025

(54) SUBSTRATE PROCESSING APPARATUS AND SUBSTRATE PROCESSING METHOD

(71) Applicant: Tokyo Electron Limited, Tokyo (JP)

(72) Inventors: Tatsuya NAGAMATSU, Kumamoto (JP); Takao INADA, Kumamoto (JP); Yuta HAMASHIMA, Kumamoto (JP); Takumi HONDA, Kumamoto (JP); Hisashi KAWANO, Kumamoto (JP); Itaru KANNO, Kumamoto (JP)

(21) Appl. No.: 18/720,641

(22) PCT Filed: Dec. 9, 2022
(86) PCT No.: PCT/JP2022/045398

§ 371 Date: Jun. 16, 2024

(30) Foreign Application Priority Data
Dec. 21, 2021 (JP) 2021-207500
Oct. 13, 2022 (JP) 2022-164972

(51) Int. Cl. H01L 21/67; H01L 21/02; H01L 21/311

(52) U.S. Cl. CPC H01L 21/67086; H01L 21/0206; H01L 21/31111; H01L 21/67051

(57) ABSTRACT

A substrate processing apparatus includes: a batch processing section that includes batch processing units each provided with a processing tank that stores a processing liquid, and immerses substrates in the processing liquid stored within the processing tank and collectively performs a liquid processing on the substrates; a single-wafer processing section that includes a single-wafer processing unit that processes the substrates processed in the batch processing section, one by one; a standby section that includes an immersion tank that stores an immersion liquid, and stands by the substrates processed by the batch processing section, while being immersed in the immersion liquid; and a conveyance system that conveys the substrates from the standby section to the single-wafer processing section, and includes a first substrate conveyance unit that takes out the substrates immersed in the immersion liquid within the immersion tank one by one from the immersion liquid.

### TECHNICAL FIELD

The present invention relates to a substrate processing apparatus and a substrate processing method.

### BACKGROUND

In manufacturing semiconductor devices, a chemical liquid is supplied to a substrate such as a semiconductor wafer so that a liquid processing such as a wet etching process or a cleaning process is performed on the substrate. Patent Document 1 describes a substrate processing system that performs such a liquid processing on substrates. The substrate processing system includes a chemical liquid tank, a washing tank, a washing buffer tank, a transfer section, and a rotary-drying section. In the chemical liquid tank, a batch-type chemical processing is performed on a plurality of substrates, in the washing tank, a batch-type washing processing is performed on the substrates that have been subjected to the chemical processing, and in the rotary-drying section, a single-wafer type shake-off drying process is performed on each of the substrates which have been subjected to the washing processing. In the washing buffer tank, the substrates which have been subjected to the washing processing are temporarily stored in water. The transfer section transfers the substrates stored in the washing buffer tank one by one, to the rotary-drying section.

### PRIOR ART DOCUMENT

### Patent Document

Patent Document 1: Japanese Patent Publication No. 3192951

### SUMMARY OF THE INVENTION

The present disclosure provides a technology that prevents the deterioration of a surface state of a substrate when the substrate is conveyed from a batch processing section to a single-wafer processing section.

A substrate processing apparatus according to one embodiment of the present disclosure includes: a batch processing section that includes a plurality of batch processing units each provided with a processing tank that stores a processing liquid, and immerses a plurality of substrates in the processing liquid stored within the processing tank and collectively performs a liquid processing on the plurality of substrates; a single-wafer processing section that includes a single-wafer processing unit that processes the plurality of substrates processed in the batch processing section, one by one; a standby section that includes an immersion tank that stores an immersion liquid, and stands by plurality of substrates processed by the batch processing section, while being immersed in the immersion liquid; and a conveyance system that conveys the plurality of substrates from the standby section to the single-wafer processing section, and includes a first substrate conveyance unit that takes out the plurality of substrates immersed in the immersion liquid within the immersion tank one by one from the immersion liquid. The standby section performs at least one of a first liquid processing and a second liquid processing, on the substrates, the first liquid processing is a liquid processing that hydrophilizes the surfaces of the substrates, or a liquid processing that improves or maintains hydrophilicity of the surfaces of the substrates, and the second liquid processing is a liquid processing that makes a zeta potential of the surfaces of the substrates negative.

According to an embodiment of the present disclosure, it is possible to prevent deterioration of a surface state of a substrate when the substrate is conveyed from a batch processing section to a single-wafer processing section.

### BRIEF DESCRIPTION OF THE DRAWINGS

FIG. 1 is a schematic horizontal cross-sectional view of a substrate processing system according to one embodiment of a substrate processing apparatus.

FIG. 2 is a schematic side view illustrating one configuration example of a standby unit and devices related thereto.

FIG. 3 is a schematic plan view illustrating one configuration example of the standby unit and devices related thereto.

FIG. 4 is a schematic front view illustrating the operation of a third substrate conveyance robot taking out a substrate from a substrate holder of the standby unit.

FIG. 5 is a schematic front view illustrating the operation when the substrate holder of the standby unit receives the substrate from a second substrate conveyance robot.

FIG. 6 is a schematic vertical cross-sectional view illustrating one configuration example of a single-wafer type liquid processing unit.

FIG. 7 is a schematic vertical cross-sectional view illustrating one configuration example of a supercritical drying unit.

FIG. 8 is a schematic vertical cross-sectional view illustrating one configuration example of a substrate transfer unit.

FIG. 9 is a schematic cross-sectional view illustrating the structure of an etching target in a specific example 1 of a substrate processing method.

FIG. 10 is a schematic cross-sectional view illustrating the structure of an etching target in specific examples 2 and 3 of the substrate processing method.

FIG. 11 is a schematic vertical cross-sectional view of an immersion tank illustrated in a first configuration example of a standby section according to another embodiment of the substrate processing apparatus.

FIG. 12 is a schematic vertical cross-sectional view of an immersion tank illustrated in a second configuration example of the standby section according to another embodiment of the substrate processing apparatus.

FIG. 13 is a schematic vertical cross-sectional view of an immersion tank illustrated in a third configuration example of the standby section according to another embodiment of the substrate processing apparatus.

FIG. 14 is a schematic vertical cross-sectional view of an immersion tank illustrated in a fourth configuration example of the standby section according to another embodiment of the substrate processing apparatus.

FIG. 15 is a Pourbaix diagram for explaining metal loss of tungsten.

### DETAILED DESCRIPTION TO EXECUTE THE INVENTION

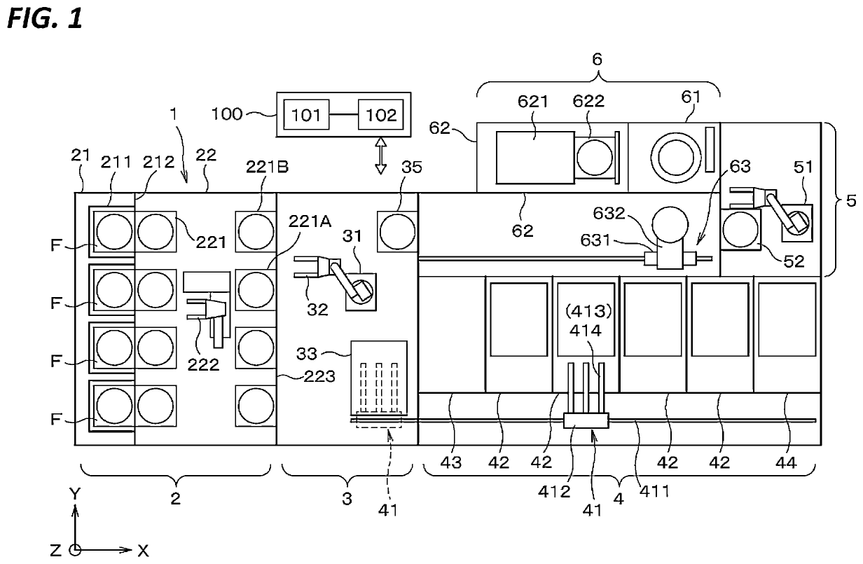

Hereinafter, descriptions will be made on a substrate processing system 1 according to an embodiment of a substrate processing apparatus of the present disclosure with reference to the accompanying drawings. In order to simplify the explanation regarding directions, an XYZ orthogonal coordinate system is set, and is displayed at the lower left of FIG. 1. The Z direction is an up-down (e.g., vertical) direction and the positive Z direction is an upward direction.

As illustrated in FIG. 1, the substrate processing system 1 according to an embodiment of the substrate processing apparatus of the present disclosure includes a container loading/unloading section 2, a first interface section 3, a batch processing section 4, a second interface section 5, and a single-wafer processing section 6.

The substrate processing system 1 includes a control device 100. The control device 100 includes a computer, and includes an arithmetic processor 101 and a storage 102. The storage 102 stores programs (also including processing recipes) that control various processes to be executed in the substrate processing system 1. The arithmetic processor 101 controls the operation of each component of the substrate processing system 1 to be described below by reading and executing the program stored in the storage 102, so that a series of processes to be described below are executed. The control device 100 may include user interfaces such as a keyboard, a touch panel, and a display. The above programs may be recorded in a computer-readable storage medium, and may be installed to the storage 102 of the control device 100 from the storage medium. Examples of the computer-readable storage medium include hard disks (HD), flexible disks (FD), compact discs (CD), magnetic optical discs (MO), and memory cards.

The container loading/unloading section 2 includes a stage section 21 on which substrate conveyance containers F such as front operating universal pods (FOUPs) (hereinafter, simply referred to as “containers F” for convenience) are placed, and a container stock section 22 that stores the containers F. The stage section 21 is provided with a plurality of (four in the illustrated example) movable tables 211 aligned in the Y direction. A partition wall 212 is provided between the stage section 21 and the container stock section 22. An opening (not illustrated) with a shutter is provided at the position of the partition wall 212 corresponding to each movable table 211. The container F placed on the movable table 211 may be moved into the container stock section 22 through the opening whose shutter is open.

The container stock section 22 is provided with a plurality of container holding stages 221, and a container conveyance robot (a container conveyance mechanism) 222. The container conveyance robot 222 may transfer the containers F between the movable table 211 located within the container stock section 22, and any container holding stage 221. Among the container holding stages 221, one (or two) present on the first interface section 3 side is a substrate take-out stage 221A, and another is a substrate storage stage 221B.

A partition wall 223 is provided between the container stock section 22 and the first interface section 3. An opening (not illustrated) with a shutter and a mechanism (not illustrated) for opening/closing the lid of the container F are provided at the position of the partition wall 223 corresponding to the substrate take-out stage 221A.

A first substrate conveyance robot (a first conveyance mechanism) 31 is provided within the first interface section 3. The first substrate conveyance robot 31 has a plurality of substrate holders 32 (e.g., 5 to 25 substrate holders 32) as an end effector. The first substrate conveyance robot 31 collectively takes out a plurality of substrates W (e.g., 5 to 25 substrates W), from the container F placed on the substrate take-out stage 221A, and transfers the substrates W to a second substrate conveyance robot 41 (a second conveyance mechanism) (indicated by a broken line) waiting in a transfer area 33. Here, after the horizontal-posture substrates W accommodated within the container F are taken out of the container F, the first substrate conveyance robot 31 performs a conversion into the vertical posture, and then transfers the substrates W to the second substrate conveyance robot 41.

Meanwhile, 50 substrates (corresponding to two containers) may be processed at a time in the batch processing section 4. In this case, the end effector of the first substrate conveyance robot 31 may be provided with a pitch change mechanism that changes the distance between the substrate holders 32, or the transfer area 33 may be provided with a pitch change mechanism. The pitch change mechanism is, for example, a mechanism that sets the arrangement interval (pitch) of the substrates W, to ½ of the arrangement interval of the substrates W accommodated in the container F, and is well known in the corresponding technical field.

In the following description, descriptions will be made on the assumption that one batch is made up of 25 substrates W (25 substrates are simultaneously processed for each process in the batch processing section 4).

A plurality of batch processing units 42 is provided in the batch processing section 4. Although four batch processing units 42 are depicted in FIG. 1, the number of batch processing units 42 is not limited to this. The batch processing units 42 are provided depending on the number corresponding to processes to be performed on the substrates W. The basic configurations of the batch processing units 42 are substantially the same, and a processing tank that stores a processing liquid, a substrate holder (referred to as, e.g., a wafer boat) that holds substrates within the processing tank, and an elevating mechanism that moves the substrate holder up and down are included. The substrate holder may hold, for example, 25 substrates W in a vertical posture, at equal intervals in the horizontal direction. The batch processing units 42 are aligned in the X direction.

The plurality of batch processing units 42 may include a versatile batch processing unit that can handle various types of processes, and a batch processing unit dedicated to a specific process. As the latter, a batch processing unit for a phosphoric acid (H₃PO₄) processing is exemplified. In the phosphoric acid processing, in general, the processing liquid within the processing tank is at a high temperature and is placed approximately in a boiling state, and moreover, bubbling may be performed. In order to handle such a processing, the batch processing unit for the phosphoric acid processing is additionally provided with, for example, a lid that closes the upper opening of the processing tank, a mechanism for monitoring and maintaining the boiling state of the processing liquid, a bubbling nozzle, and a mechanism for pressing the substrates against the substrate holder.

The plurality of batch processing units 42 includes, for example, a first chemical processing unit, a first rinsing processing unit, a second chemical processing unit, and a second rinsing processing unit. The substrates W are sequentially put into the first chemical processing unit, the first rinsing processing unit, the second chemical processing unit, and the second rinsing processing unit, and are subjected to a processing (a chemical processing or a deionized water (DIW) rinsing processing) depending on the liquid stored in the processing tank, in each batch processing unit 42. Specific examples of the processing performed in the batch processing unit 42 are described below.

A cleaning unit 43, which cleans a substrate holding portion 413 of the second substrate conveyance robot 41 and performs drying as necessary, is provided at a position in the batch processing section 4 closest to the first interface section 3.

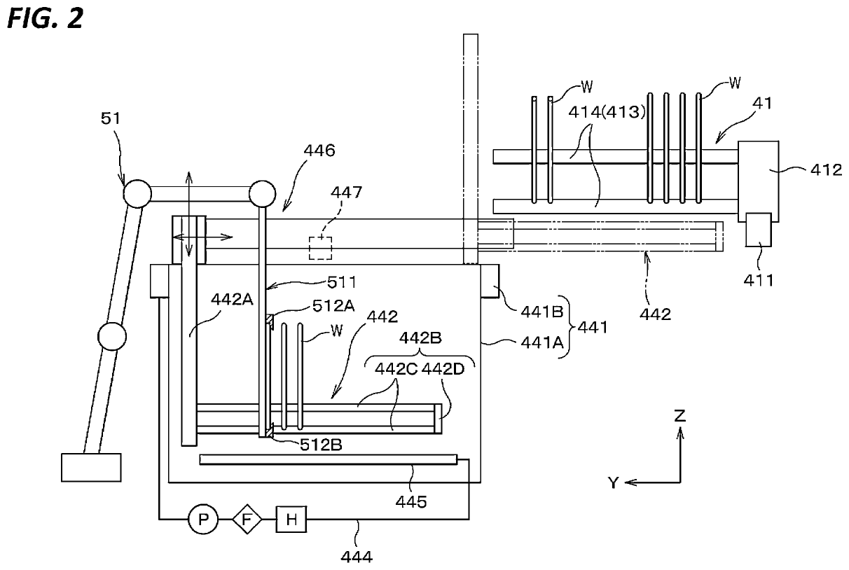

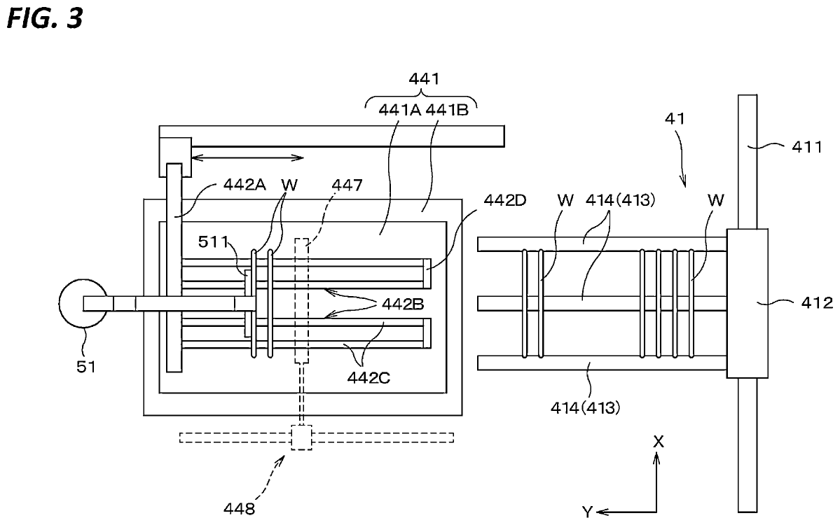

A standby unit (a standby section) 44 is provided at a position in the batch processing section 4 farthest from the first interface section 3. The standby unit 44 includes: an immersion tank 441 that stores an immersion liquid in which the substrates W are to be immersed; a substrate holder 442 (referred to as, e.g., a wafer boat) that holds the substrates within the immersion tank 441, and a moving mechanism 443 that moves the substrate holder 442 up and down or in the horizontal direction (see, e.g., FIG. 2 and FIG. 3). The substrate holder 442 may hold, for example, 25 substrates W in a vertical posture, at equal intervals in the horizontal direction. In the standby unit 44, a process is performed to change the surface state of the substrate W in preparation for subsequent single-wafer conveyance. This process is, specifically, for example, a hydrophilization processing for preventing liquid shortage on the surface of the substrate W, or a process by which the zeta potential of the surface of the substrate W is made negative so as to prevent particles from adhering to the surface of the substrate W. The detailed configuration of the standby unit 44 will be described below.

The processing liquid, which is stored in the batch processing unit 42 into which the substrates W are put immediately before being put into the standby unit 44, must not be one that interferes with the processing to be performed in the standby unit 44, and is usually a rinsing liquid, specifically, for example, DIW.

The batch processing section 4 is provided with the aforementioned second substrate conveyance robot 41. The second substrate conveyance robot 41 includes a guide rail 411 that extends along the arrangement direction (X direction) of the batch processing units 42, a traveling body 412 that can run along the guide rail 411, and the substrate holding portion 413 attached to the traveling body 412.

The substrate holding portion 413 includes, for example, three substrate holding rods 414 extending in the Y direction. Each substrate holding rod 414 has substrate holding grooves (not illustrated) arranged at equal intervals along the Y direction. The peripheral edge of the substrate W is fitted into each substrate holding groove, and then 25 substrates W are held in a vertical posture by the substrate holding portion 413, at equal intervals along the Y direction.

One end of the guide rail 411 extends to the front portion of the transfer area 33 within the first interface section 3. Thus, as described above, at the portion of the transfer area 33, substrates may be transferred between the first substrate conveyance robot 31 and the second substrate conveyance robot 41. The other end of the guide rail 411 extends to the front portion of the standby unit 44. Thus, the second substrate conveyance robot 41 may transfer substrates to/from the standby unit 44, and any batch processing unit 42. Further, the substrate holding portion 413 of the second substrate conveyance robot 41 may also access the cleaning unit 43 in order to clean the substrate holding portion 413.

A third substrate conveyance robot 51, and one or more (e.g., two) substrate transfer units 52 are provided within the second interface section 5. When the plurality of substrate transfer units 52 is provided, for example, these may be provided by being vertically stacked.

The third substrate conveyance robot 51 may take out the substrates W held by the substrate holder 442 in the immersion tank 441 of the standby unit 44, one by one, convert the vertical posture of the above substrate W into the horizontal posture, and then place the substrate W on the substrate transfer unit 52.

The single-wafer processing section 6 is provided with one or more single-wafer type liquid processing units (single-wafer processing units) 61, one or more supercritical drying units 62 which perform supercritical drying on the substrates W processed by the single-wafer type liquid processing units 61, and a fourth substrate conveyance robot 63. When the plurality of single-wafer type liquid processing units 61 and the plurality of supercritical drying units 62 are provided, for example, these may be provided by being vertically stacked. The single-wafer type liquid processing unit 61 and the supercritical drying unit 62 are single-wafer processing units that process one substrate W at a time.

The fourth substrate conveyance robot 63 includes an end effector movable by, for example, a multi-axis drive mechanism 631 that may move in the X direction and the Y direction, may move up/down in the Z direction, and may rotate around the vertical axis. The end effector is, for example, a fork-shaped substrate holder 632 that may hold one substrate. The fourth substrate conveyance robot 63 may perform loading/unloading of substrates between the substrate transfer unit 52 within the second interface section 5, the single-wafer type liquid processing unit 61, and the supercritical drying unit 62, and a substrate transfer unit 35 within the first interface section 3. While being transported by the fourth substrate conveyance robot 63, the substrate W is always maintained in a horizontal posture.

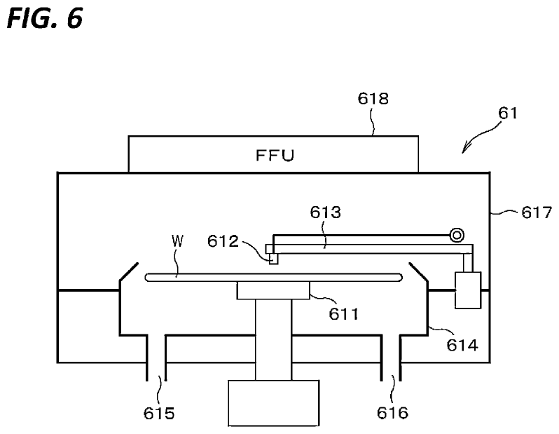

As the single-wafer type liquid processing unit 61, any unit known in the technical field of semiconductor manufacturing apparatuses may be used. The configuration example of the single-wafer type liquid processing unit 61 that may be used in the present embodiment will be briefly described below with reference to FIG. 6. The single-wafer type liquid processing unit 61 includes a spin chuck 611 that can hold the substrate W in a horizontal posture and rotate the substrate W around the vertical axis, and one or more nozzles 612 that discharge a processing liquid to the substrate W held and rotated by the spin chuck 611. The nozzle 612 is carried by an arm 613 for moving the nozzle 612. The single-wafer type liquid processing unit 61 has a liquid receiving cup 614 that collects the processing liquid scattered from the rotating substrate W. The liquid receiving cup 614 has a liquid drain port 615 through which the collected processing liquid is discharged to the outside of the single-wafer type liquid processing unit 61, and an exhaust port 616 through which the atmosphere inside the liquid receiving cup 614 is discharged. Clean gas (clean air) blows downwards from a fan filter unit 618 provided in the ceiling of a chamber 617 of the single-wafer type liquid processing unit 61, is drawn into the liquid receiving cup 614, and is discharged through the exhaust port 616.

In the present embodiment, the fourth substrate conveyance robot 63 takes out the substrate W from the substrate transfer unit 52 in the second interface section 5, and carries the substrate W into the single-wafer type liquid processing unit 61. In the single-wafer type liquid processing unit 61, a DIW rinsing processing, an IPA replacement process, and an IPA puddle forming process are sequentially performed. In the DIW rinsing processing, DIW is supplied from the nozzle 612 to the surface of the rotating substrate W, and the liquid that has previously adhered to the surface of the substrate W is washed with DIW. In the IPA replacement process, IPA is supplied from the nozzle 612 to the surface of the continuously rotating substrate W, and DIW on the surface of the substrate W is replaced with IPA. In the IPA puddle forming process, while IPA is continuously supplied from the nozzle 612, the rotational speed of the substrate is significantly reduced, so that a relatively thick liquid film of IPA is formed on the surface of the substrate W, and then the rotation of the substrate is stopped.

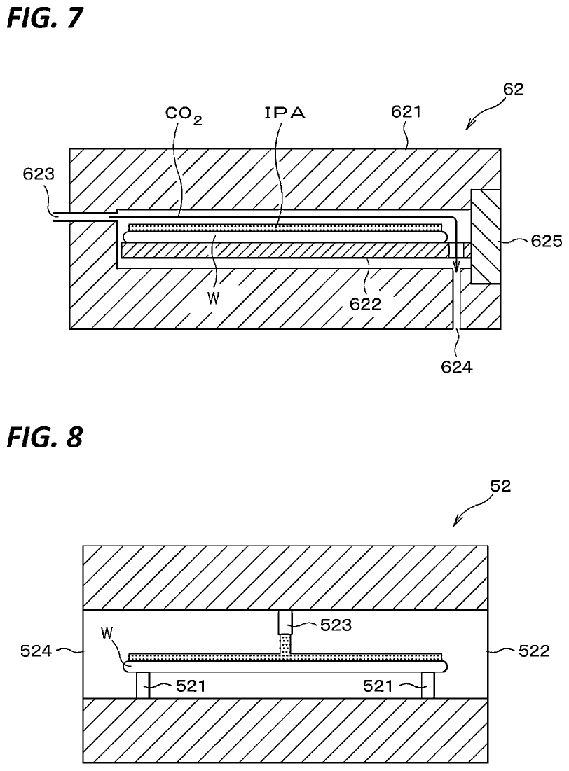

As the supercritical drying unit 62, any unit known in the technical field of semiconductor manufacturing apparatuses may be used. The configuration example and operation of the supercritical drying unit 62 that may be used in the present embodiment will be briefly described below with reference to FIG. 7. The supercritical drying unit 62 includes a supercritical chamber 621, and a substrate support tray 622 that may advance/retreat to/from the supercritical chamber 621. In FIG. 1, the substrate support tray 622 that has left the supercritical chamber 621 is depicted. In this state, the fourth substrate conveyance robot 63 transfers the substrate W to the substrate support tray 622.

The substrate W on which the IPA puddle is formed is taken out of the single-wafer type liquid processing unit 61 by the fourth substrate conveyance robot 63, and is placed on the substrate support tray 622 of the supercritical drying unit 62. Next, the substrate support tray 622 is accommodated within the supercritical chamber 621, and a lid 625 integrated with the substrate support tray 622 seals the supercritical chamber 621. In this state, a supercritical fluid (e.g., supercritical carbon dioxide (CO₂)) is supplied into the supercritical chamber 621 through a supply port 623 from a supercritical fluid supply source (not illustrated), and flows along the arrow in the drawing and is discharged from a discharge port 624. Until the pressure inside the supercritical chamber 621 is increased, CO₂ may be supplied through a separate supply port (not illustrated) that is open toward the bottom surface of the substrate support tray 622. The IPA on the substrate W is replaced with supercritical CO₂ that flows in the vicinity thereof. After the IPA is replaced with the supercritical CO₂, the pressure inside the supercritical chamber 621 is returned to normal pressure. This vaporizes supercritical CO₂, thereby drying the surface of the substrate W. In this manner, it is possible to dry the substrate W while preventing the collapse of the pattern formed on the surface of the substrate W.

The dried substrate is taken out of the supercritical drying unit 62 by the fourth substrate conveyance robot 63, and is carried into the substrate transfer unit 35 provided within the first interface section 3. The first substrate conveyance robot 31 of the first interface section 3 takes out the substrates W from the substrate transfer unit 35, and allows the processed substrates W to be accommodated in the container F placed on the substrate storage stage 221B.

The container F containing the processed substrates W is placed on the movable table 211 by the container conveyance robot 222 of the container stock section 22 while being taken out to the stage section 21.

Next, regarding the batch processing section 4 (e.g., its standby unit 44) and the second interface section 5, detailed descriptions will be made on one configuration example and the operation thereof with reference to FIGS. 2 to 5 and FIG. 8.

FIG. 2 and FIG. 3 illustrate the second substrate conveyance robot 41 and the third substrate conveyance robot 51 together with the standby unit 44.

As described above, the standby unit 44 includes the immersion tank 441. The immersion tank 441 includes an inner tank 441A that stores an immersion liquid, and an outer tank 441B that receives the immersion liquid overflowing from the inner tank 441A. The immersion liquid that has flowed out to the outer tank 441B flows into a circulation line 444, and is discharged toward the substrates W from a nozzle 445 provided within the inner tank 441A. The nozzle 445 may be a bar nozzle that has discharge ports aligned at equal intervals along the arrangement direction of the substrates W within the inner tank 441A. In the circulation line 444, a pump for forming a circulation flow, a filter for removing particles, and a temperature controller for controlling the temperature of the immersion liquid, e.g., a heater, are interposed.

As described above, the standby unit 44 includes the substrate holder 442 that holds substrates within the immersion tank 441. The substrate holder 442 includes a plate-like base 442A extending in the vertical direction (the Z direction), and two support member sets 442B extending from the base 442A in the horizontal direction (the Y direction). Each support member set 442B includes two support rods 442C whose base ends are fixed to the base 442A, and a fixing member 442D that fixes the distal ends of the two support rods 442C to each other. On each support rod 442C, substrate holding grooves (not illustrated), which position the substrates W relative to the Y direction by receiving the peripheral edges of the substrates W, are formed at equal intervals in the Y direction. The substrate holder 442 may hold a plurality of (e.g., 25) substrates W in a vertical posture at equal intervals in the Y direction.

The standby unit 44 includes a moving mechanism 446 that may move the substrate holder 442 in the Y direction and the Z direction. The moving mechanism 446 may move the substrate holder 442 between a transfer position (indicated by the two-dot chain line in FIG. 2) at which the substrates are transferable to/from the second substrate conveyance robot 41, and an immersion position (indicated by the solid line in FIG. 3) at which the held substrates W are immersed in the immersion liquid stored within the immersion tank 441.

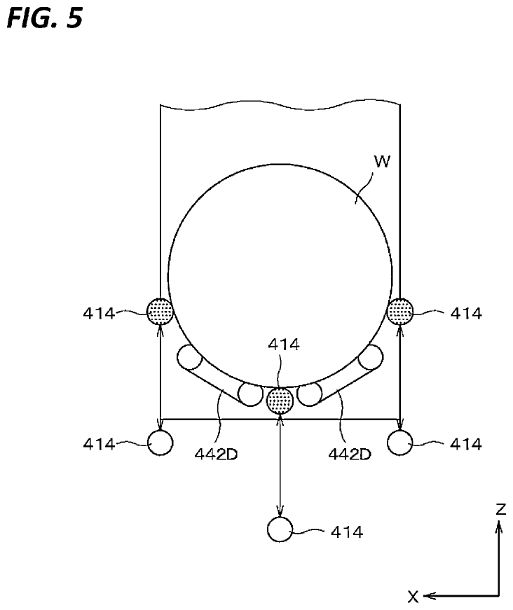

As illustrated in FIG. 5, the two support member sets 442B of the substrate holder 442 of the standby unit 44 may pass through gaps between three substrate holding rods 414 constituting the substrate holding portion 413 of the second substrate conveyance robot 41. Thus, by relatively moving the substrate holder 442 (the support members 442B) and the substrate holding portion 413 (the substrate holding rods 414) in the Z direction, it is possible to collectively transfer the plurality of substrates W between the support members 442B and the substrate holding rods 414.

The arrows in FIG. 5 indicate the relative movement between the support members 442B and the holding rods 413A in the up-down direction. When the substrate holding rods 414 indicated by filled circles in FIG. 5 are located further above the support members 442B, the substrates W which have been held by the support members 442B are held by the substrate holding rods 414. When the relative movement opposite to the above is performed, the substrates W which have been held by the substrate holding rods 414 are held by the support members 442B.

As is clear from the above description, the configuration of the standby unit 44 is the same as that of the batch-type liquid processing apparatus known in the corresponding technical field. That is, the configuration of the batch processing unit 42 in the present embodiment may be the same as the configuration of the standby unit 44, and the transfer of substrates W between the batch processing unit 42 and the second substrate conveyance robot 41 may also be performed in the same manner. Therefore, descriptions regarding the configuration of the batch processing unit 42 will be omitted. Main differences between the batch processing unit 42 and the standby unit 44 are such that the standby unit 44 may be accessed by not only the second substrate conveyance robot 41 but also the third substrate conveyance robot 51, and the liquid stored in the tank.

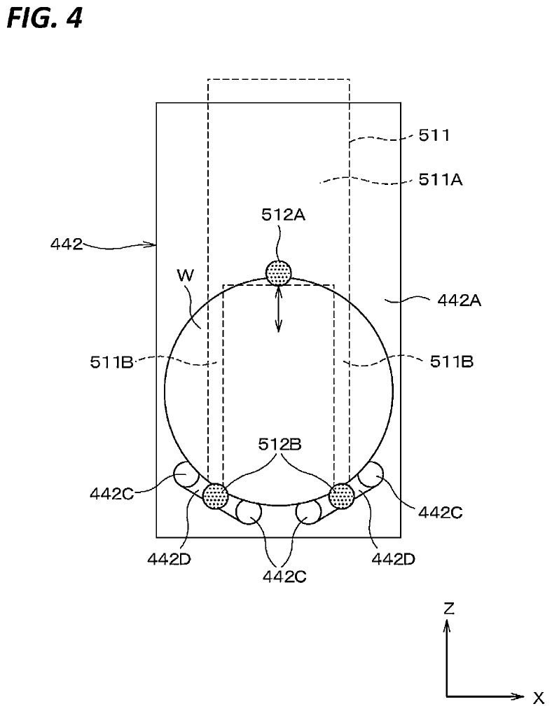

The third substrate conveyance robot 51 is configured as a single-wafer type conveyance robot. The end effector of the third substrate conveyance robot 51 is configured as a thin-plate-like single substrate holder 511. In one illustrated embodiment, the substrate holder 511 includes a base portion 511A, and a pair of elongated distal end portions 511B connected to the base portion 511A. Each distal end portion 511B has a size by which the distal end portion 511B may be inserted between two support rods 442C constituting each support member 442B of the substrate holder 442 (see FIG. 4).

As illustrated in FIG. 2 and FIG. 4, the substrate holder 511 includes a plurality (three in the illustrated example) of gripping claws 512A and 512B (schematically indicated by circles filled with dots in FIG. 4). In the illustrated example, the movable griping claw 512A is provided at the distal end of the base portion 511A of the substrate holder 511, and the fixed griping claw 512B is provided at the distal end of each distal end portion 5111B. The griping claws 512A and 512B have shapes engageable with the peripheral edge of the substrate W (a region near APEX).

As illustrated in FIG. 2 and FIG. 3, the substrate holder 511 is brought close to the substrate W in the Y direction, and the movable griping claw 512A and the fixed griping claws 512B are located at positions slightly away from the peripheral edge of the substrate W in a state where the movable griping claw 512A is kept away from the fixed griping claws 512B. From this state, by moving the movable griping claw 512A closer to the fixed griping claws 512B, it is possible to clamp the substrate W by the movable griping claw 512A and the fixed griping claws 512B. Next, by moving the substrate holder 511 directly upwards (in the positive Z direction), the substrate W may be taken out while the peripheral edge of the substrate W is extracted from substrate holding grooves (not illustrated) of the support rods 442C of the substrate holder 442.

The third substrate conveyance robot 51 may be configured as a multi-axis robot (for example, one having an X axis, a Y axis, a Z axis, and a θ axis), or as an articulated robot as long as it is configured to satisfy the following functions (1) and (2).

(1) Any substrate W held by the substrate holder 442 in the inner tank 441A may be moved in the vertical direction (the positive Z direction) and may be taken out of the inner tank 441A while being clamped by the substrate holder 511.

(2) It is possible to convert the vertical posture of the substrate W in the inner tank 441A, into a horizontal posture, and place the substrate W on the substrate transfer unit 52.

FIGS. 1 to 3 schematically illustrate the third substrate conveyance robot 51 configured as an articulated robot.

As illustrated in FIG. 2 and FIG. 3, a spray nozzle 447 may be attached to the immersion tank 441. The spray nozzle 447 may be moved in the Y direction by a Y-direction moving mechanism 448 (illustrated only in FIG. 3) slightly above the liquid surface of the immersion liquid stored in the inner tank 441A. The spray nozzle 447 may spray a spray liquid to the surface of the substrate W while or immediately after the substrate W is lifted from the immersion liquid by the third substrate conveyance robot 51. It is desirable that the spray nozzle 447 is configured to evenly spray the spray liquid to the surface of the substrate W. The spray nozzle 447 may be configured as, for example, a bar nozzle having discharge ports aligned at equal intervals along the X direction. In this case, the spray nozzle 447 sprays the spray liquid to the surface of the substrate W while being positioned by the Y-direction moving mechanism 448 at a position close to and facing the surface of the substrate W being lifted by the third substrate conveyance robot 51.

The third substrate conveyance robot 51 carries the substrate W taken out of the immersion tank 441, into the substrate transfer unit 52 after performing a conversion into a horizontal posture. The substrate transfer unit 52 is a unit that mediates the transfer of the substrate W between the third substrate conveyance robot 51 and the fourth substrate conveyance robot 63. One configuration example of the substrate transfer unit 52 is schematically illustrated in FIG. 8. The third substrate conveyance robot 51, the substrate transfer unit 52 and the fourth substrate conveyance robot 63 constitute a conveyance system that conveys the substrate W from the batch processing section 4 (the standby unit 44) to the single-wafer processing section 6.

The substrate transfer unit 52 has a plurality of (e.g., three) support pins 521 as substrate support members. The third substrate conveyance robot 51 carries the substrate W into the substrate transfer unit 52 through a loading port 522, and places the substrate W in a horizontal posture, on the support pins 521. A coating liquid nozzle 523 that discharges a coating liquid to the surface of the substrate W is provided on the ceiling of the substrate transfer unit 52. The coating liquid nozzle 523 supplies the coating liquid such that the puddle (e.g., a liquid film) of the coating liquid is formed over the entire surface of the substrate W. The coating liquid is, for example, DIW, but is not limited thereto. It may be a processing liquid for a zeta potential negative processing to be described below.

A liquid film thickness sensor (not illustrated) or a camera (not illustrated) may be provided on the ceiling of the substrate transfer unit 52, so that the coating liquid may be supplied to the surface of the substrate W from the coating liquid nozzle 523 only when the liquid film of the surface of the substrate W is likely to break due to drying, etc. Alternatively, the coating liquid may be supplied to the surface of the substrate W from the coating liquid nozzle 523 only when the substrate W remains in the substrate transfer unit 52 over a long period of time to such an extent that there is a risk of drying of the surface of the substrate W (this means that at least a part of the surface is exposed to the atmosphere). In this case, the residence time of the substrate W within the substrate transfer unit 52 may be measured by a timer. In the above case, the control device 100 causes the coating liquid to be discharged to the substrate W from the coating liquid nozzle 523 on the basis of the detection result of the sensor or the camera, or on the basis of the timekeeping result of the timer.

When a substrate transfer becomes possible for the single-wafer type liquid processing unit 61 into which the above substrate W is scheduled to be carried, the substrate W placed in the substrate transfer unit 52 is taken out by the fourth substrate conveyance robot 63 through an unloading port 524 and is carried into the single-wafer type liquid processing unit 61. Then, the path through which the substrate W progresses is as described above.

Next, descriptions will be made on a liquid (an immersion liquid, a spray liquid) to be supplied to the substrate W in the standby unit 44 and a liquid (a coating liquid) to be supplied to the substrate W in the substrate transfer unit 52. Problems that may occur during conveyance from the batch processing section 4 to the single-wafer processing section 6 may include the followings.

If the surface of the substrate is hydrophobic after the last chemical processing is performed on the substrate W in the batch processing section 4, there is a possibility that a liquid shortage may occur and a part of the surface of the substrate may be exposed during conveyance from the batch processing section 4 to the single-wafer processing section 6. The exposure of the surface of the substrate may cause the collapse of a pattern on the substrate surface, or the occurrence of defects, such as particles and water marks, on the substrate surface (problem 1).

If the substrate surface is positively charged after the last chemical processing is performed on the substrate W in the batch processing section 4, the possibility that particles floating in the liquid will adhere to the substrate increases. This is because the zeta potential of the particles and the zeta potential of the substrate surface are opposite (problem 2).

In the present embodiment, a liquid processing is performed in the standby unit 44 so as to solve at least one of the above problems 1 and 2.

The liquid processing for solving the above problem 1 is a processing that hydrophilizes the substrate surface (hereinafter, referred to as a “hydrophilization processing” for convenience). The hydrophilization processing requires a relatively long time, and thus is performed by immersing the substrate in the immersion liquid (e.g., a processing liquid for hydrophilization processing) stored in the immersion tank 441 of the standby unit 44. As for the hydrophilization processing liquid, for example, any one of the followings may be used.
SC₂
Ozonated water
Hydrogen peroxide solution (H₂O₂)
Sulfuric acid hydrogen peroxide mixture (SPM)

The actual hydrophilization processing liquid to be used may be determined by considering, for example, the processing liquid used in the last chemical processing executed in the batch processing section 4 (excluding the DIW rinsing processing which is a final process) and the surface state of the processed substrate W (the material and chemical state of the exposed surface (whether a hydrophilic group is present at the end, etc.)). Specific examples of processing are described below.

In the present embodiment, at least 25 substrates are simultaneously immersed in the hydrophilization processing liquid within the immersion tank 441 and then are taken out one by one. That is, the immersion time is considerably different between a substrate that is taken out first and a substrate that is taken out last. Therefore, the hydrophilization processing liquid must not be one that etches the substrate surface up to a problematic level. Although, not limited, the temperature of the hydrophilization processing liquid may be room temperature from the viewpoint of suppressing etching (however, this is not limited to room temperature).

The liquid processing for solving the above problem 2 is a processing through which a liquid (liquid film) that may make the zeta potential of the substrate surface negative is allowed to adhere to the surface of the substrate W (hereinafter, referred to as a “zeta potential negative processing” for convenience). The zeta potential negative processing takes effect in a shorter time than the hydrophilization processing, and thus may be carried out by performing immersion in the immersion liquid (e.g., a processing liquid for zeta potential negative processing) within the immersion tank 441, or by spraying a spray liquid (e.g., the zeta potential negative processing liquid) to the substrate surface by the spray nozzle 447.

As for the zeta potential negative processing liquid, for example, any one of the followings may be used.
Functional water (e.g., DIW containing trace amount of ammonia water)
Tetramethylammonium hydroxide (TMAH)
Organic alkaline solution
Anionic surfactant

Although not limited, the temperature of the zeta potential negative processing liquid may be room temperature from the viewpoint of suppressing etching (however, this is not limited to room temperature).

For example, when the last chemical processing executed in the batch processing section 4 is a SC1 processing (thereafter, a DIW rinsing processing is performed), at the time of putting the substrate W into the standby unit 44, the surface of the substrate W may have been sufficiently hydrophilized. In such a case, only the zeta potential negative processing may be performed in the standby unit 44. In this case, it is also possible to perform the zeta potential negative processing by using the spray nozzle 447. Even in this case, since the substrate W must not be allowed to be exposed to the atmosphere during stand-by, it is thought that the immersion liquid within the immersion tank 441 may be a suitable non-reactive liquid, for example, DIW, and the substrate may be kept on stand-by in the immersion liquid. Also, the zeta potential negative processing may be performed by using the immersion liquid (the zeta potential negative processing liquid) within the immersion tank 441.

However, even if the surface of the substrate W is hydrophilic at the time of putting the substrate W into the standby unit 44, the hydrophilization processing liquid may be stored in the immersion tank 441, so as to perform a process of further increasing the hydrophilicity or at least maintaining hydrophilicity.

As described above, when the substrate W has a hydrophilized surface, and has a surface with a negative zeta potential while leaving the standby unit 44, the following advantageous effects are obtained.

When the substrate W has a hydrophilized surface while leaving the standby unit 44, it is possible to prevent a liquid shortage on the surface of the substrate W (the loss of a liquid film in a part of the entire surface of the substrate) during lift-up of the substrate W from the immersion liquid in the immersion tank 441. Further, while the substrate W is being conveyed from the batch processing section 4 to the single-wafer processing section 6, it is possible to prevent the occurrence of a liquid shortage on the surface of the substrate W. Therefore, it is possible to prevent defects, such as particles or watermarks, from occurring on the substrate surface, or pattern collapse from occurring due to exposure of the surface of the substrate W to the atmosphere.

Alternatively, according to the embodiment, even if a conveyance distance from the batch processing section 4 to the single-wafer processing section 6 or the time required for conveyance becomes slightly longer, problems are less likely to occur. This means that an optimum layout may be employed for each of the batch processing section 4 and the single-wafer processing section 6. That is, there is no need to employ an unreasonable layout in order to shorten the conveyance distance or the time required for the conveyance. Further, in many cases, it is difficult to perfectly match the processing schedules of batch processing and single-wafer processing, and some waiting time has to be set to carry the substrates W into the single-wafer processing unit. According to the embodiment, since a liquid shortage is less likely to occur on the surface of the substrate W, even if some waiting time is set, problems are less likely to occur. Therefore, flexibility in setting a conveyance schedule and a processing schedule is improved. Further, when the transfer unit 52 having the coating liquid nozzle 523 is provided between the batch processing section 4 and the single-wafer processing section 6, it is possible to further reduce the possibility that a liquid shortage will occur on the surface of the substrate W during conveyance of the substrate W from the batch processing section 4 to the single-wafer processing section 6.

Further, when the substrate W has a surface with a negative zeta potential while leaving the standby unit 44, it is possible to prevent or significantly suppress particles contained in the liquid film on the surface of the substrate W, from adhering to the surface of the substrate W during conveyance of the substrate W from the batch processing section 4 to the single-wafer processing section 6. This also eliminates the need to employ an unreasonable layout so as to shorten the conveyance distance or the time required for conveyance, and improves the flexibility of setting a conveyance schedule and a processing schedule (this is because particle adhesion caused by zeta potential also tends to increase over time).

As described above, according to the present embodiment, when the substrate W is conveyed from the batch processing section 4 to the single-wafer processing section 6, deterioration of the surface state of the substrate W may be prevented.

Hereinafter, descriptions will be made on specific examples of a combination of processing performed in each processing unit of the batch processing section 4, with a hydrophilization processing and/or a zeta potential negative processing performed in the standby unit 44.

### Specific Example 1

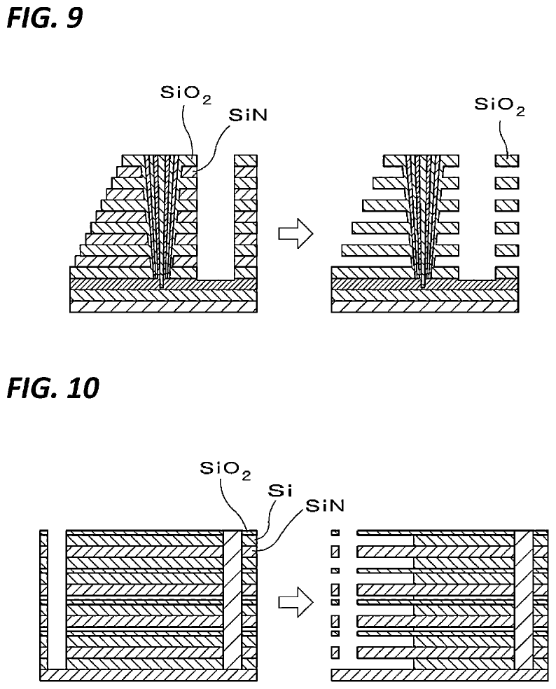

In a specific example 1, as illustrated in FIG. 9, in the batch processing section 4, selective etching is performed on a SiN film of a substrate W having a stacked structure of SiO₂/SiN of 3D-NAND (e.g., the left side of FIG. 9 is before etching, and the right side is after etching.). In this case, first, a selective etching process is performed on a SiN film by high temperature phosphoric acid in the first batch processing unit 42, and then a DIW rinsing processing is performed in the second batch processing unit 42. Next, an etching residue removal process is performed by SC1 in the third batch processing unit 42, and finally, the DIW rinsing processing is performed in the fourth batch processing unit 42. Next, the substrates are conveyed to the standby unit 44 and are immersed in the standby liquid, and then are taken out by the third substrate conveyance robot 51 one by one, and are conveyed to the single-wafer processing section 6 where a drying process is carried out according to the above described procedure.

In the specific example 1, a hydrophilization processing is not necessary in the standby unit 44 because the surface of the processed substrate (including an inner surface of a recess) has SiO₂ and is nearly hydrophilic, and furthermore, hydrophilicity is further increased by the processing with SC1 in the third batch processing unit 42. Therefore, in the standby unit 44, only a zeta potential negative processing may be performed. For example, a zeta potential negative processing liquid (e.g., weakly alkaline functional water) may be stored in the immersion tank 441, and substrates may be immersed in this. In this case, the spray nozzle 447 may not be used. In the substrate transfer unit 52 as well, the zeta potential negative processing liquid may be supplied to the substrate W.

### Specific Example 2

In a specific example 2, as illustrated in FIG. 10, in the batch processing section 4, partial selective etching is performed on a SiN film of a substrate W having a stacked structure of Si/SiO₂/SiN constituting a cell transistor module of 3D-DRAM (the left side of FIG. 10 is before etching, and the right side is after etching.). In this case, first, a selective etching process is performed on a SiN film by high temperature phosphoric acid in the first batch processing unit 42, and then the DIW rinsing processing is performed in the second batch processing unit 42. Next, the substrates are conveyed to the standby unit 44 and are immersed in the standby liquid, and then are taken out by the third substrate conveyance robot 51 one by one, and are conveyed to the single-wafer processing section 6 where a drying process is carried out according to the above described procedure. In some cases, after the processing in the second batch processing unit 42, an etching residue removal process may be performed by SC1 in the third batch processing unit 42, and then the DIW rinsing processing may be performed in the fourth batch processing unit 42, but it is assumed that such processing is not performed herein.

In the specific example 2, hydrophobic Si, hydrophilic SiO₂, and semi-hydrophobic SiN are mixed on the surface of the processed substrate (including an inner surface of a recess), but in actuality, the entire surface of the substrate is hydrophobic to semi-hydrophobic in appearance due to hydrophobic Si. Therefore, in this state, a liquid shortage is likely to occur. Thus, a hydrophilization processing is performed in the standby unit 44. Specifically, for example, a hydrophilization processing liquid (e.g., ozonated water) may be stored in the immersion tank 441 and then the substrates W may be immersed therein.

### Specific Example 3

A specific example 3 is a modification of the specific example 2, and the structure of the substrate to be processed is the same as that in the specific example 2. That is, SiN is also exposed on the surface of the substrate W (also including a surface of a recess). The surface of SiN has DIW (pH is 6 to 7) and the surface potential is close to neutrality. Thus, in this situation, particles are easily adsorbed. For this reason, in order to allow the potentials of both the SiN surface and particles to have the same sign so that they repel each other, a zeta potential negative processing is performed in the standby unit 44. The zeta potential negative processing may be performed by spraying a zeta potential negative processing liquid to the substrate W from the spray nozzle 447. In the standby unit 44, both the hydrophilization processing and the zeta potential negative processing may be performed. In this case, it is desirable to perform the hydrophilization processing within the immersion tank 441, and to perform the zeta potential negative processing by the spray nozzle 447. When the hydrophilization processing is not performed in the standby unit 44, it is also possible to perform the zeta potential negative processing in the immersion tank 441.

Next, descriptions will be made on another embodiment of a liquid processing that may be performed in the standby unit 44. In another embodiment, problems that may occur due to the long-term residence of the substrate W within the immersion tank 441 are solved.

After a plurality of (e.g., 25 to 50) substrates W is put into the immersion tank 441 of the standby unit 44, the substrates W are taken out one by one from the immersion tank 441 for the purpose of conveyance to the single-wafer processing section 6. The residence time in the immersion tank 441 is considerably different (e.g., there is a difference of several hours) between a substrate W that is taken out from the immersion tank 441 first and a substrate W that is taken out last. The following two experiments confirmed that there is a possibility that when the immersion liquid is DIW, the surface of the substrate W (e.g., bare silicon constituting a substrate W, or a metal layer exposed on the surface of the substrate W, e.g., a tungsten wiring) may be oxidized or dissolved by dissolved oxygen in DIW.

### [Experiment 1]

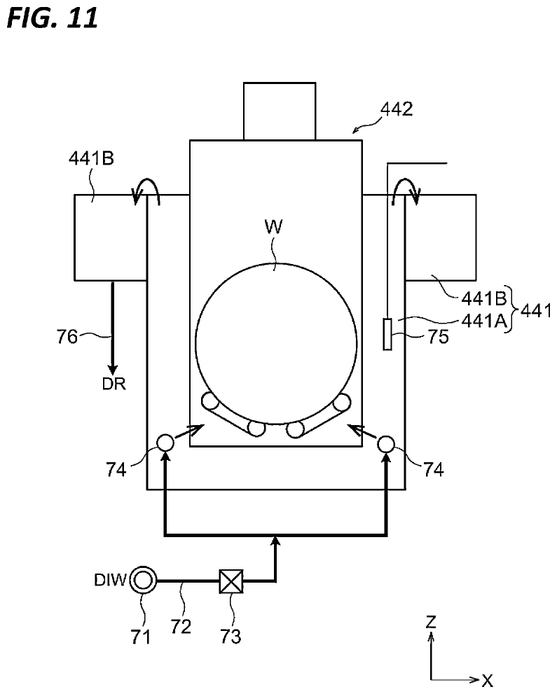

From a bare silicon substrate, a natural oxide film was removed through diluted hydrogen fluoride (DHF) chemical liquid cleaning, and then DIW rinsing was performed. Next, a test was performed such that the bare silicon substrate was immersed in DIW (e.g., dissolved oxygen concentration (DO) was about 5,000 ppb) within an immersion tank having substantially the same configuration as the immersion tank 441 described in FIG. 11. The film thickness of the natural oxide film on the surface of the bare silicon substrate was about 4 Å without DIW immersion (e.g., immediately after DIW rinsing was ended), about 6.4 Å when the DIW immersion time was 3 hr, and about 7 Å when the DIW immersion time was 5 hr. It may be found that when the bare silicon is immersed in DIW for a long time, the natural oxide film gradually grows. DIW with a DO of about 5,000 ppb is obtained by continuously supplying low-DO DIW into the immersion tank 441 at a small flow rate (e.g., about 1 to 2 L/min), as described in the configuration example 1 to be described below.

From a bare silicon substrate, a natural oxide film was removed through DHF chemical liquid cleaning, and then DIW rinsing was performed. The bare silicon substrate was finally dried, was stored in a FOUP (a substrate conveyance container), and was left within the FOUP. The film thickness of the natural oxide film on the surface of the bare silicon substrate was about 4 Å immediately after FOUP storage, and was about 4.8 Å after 6.2 hr elapsed from FOUP storage.

From the above, it may be found that immersion in DIW (DO is about 5,000 ppb) promotes the growth of a natural oxide film as compared to a case of storage within the FOUP.

### [Experiment 2]

A test was performed such that a substrate whose surface was formed with a tungsten film was immersed in DIW (e.g., DO was about 5,000 ppb) by using the same immersion tank as in the experiment 1. The film thickness reduction of the tungsten film was about 1.5 to 2.5 Å when the DIW immersion time was 3 hr, and was about 2.5 to 4.2 Å when the DIW immersion time was 5 hr. It was found that dissolution occurs on the tungsten film to a non-negligible degree in a case of long-time immersion in DIW.

The inventor believes that the dissolution of the tungsten film was caused by the following reaction.

### <Oxidation>

W+2H₂O⇒WO₂+2H₂

W+O₂⇒WO₂

If oxidation further progresses, WO₂ becomes WO₃

### <Dissolution>

WO₃+H₂O⇒H₂WO₄

H₂WO₄+H₂O⇒H₃O⁺+HWO₄⁻

HWO₄⁻+OH⁻⇒WO₄²⁻

The DIW provided for factory use usually has a dissolved oxygen concentration (DO) of about 5 ppb. If such low-DO DIW is left while being stored in the immersion tank 441, oxygen contained in the air surrounding the immersion tank 441 is dissolved in DIW, and the DO may increase to more than 10,000 ppb in some cases. When DIW is allowed to overflow from the immersion tank 441, and is circulated back to the immersion tank 441, a tendency to promote dissolution of oxygen in DIW is recognized. Such DIW in which a relatively large amount of oxygen is dissolved may result in oxidation or dissolution (e.g., a metal loss) due to the above mechanism. Regarding the configuration of the standby unit 44 that may solve this problem, descriptions will be made below with reference to FIG. 11 to FIG. 14.

### Configuration Example 1

Descriptions will be made on a configuration example 1 of the standby unit 44 and the immersion tank 441 with reference to FIG. 11. Regarding configurations of the standby unit 44 and the immersion tank 441, reference is also made to FIG. 2 as well. Components which are the same as components illustrated in FIG. 2 are given the same reference numerals.

A liquid supply nozzle 74 that supplies DIW is provided in the inner tank 411A of the immersion tank 441. To the liquid supply nozzle 74, DIW is supplied via a liquid supply line 72 whose upstream end is connected to a DIW supply source 71 for factory use. A flow controller 73 is interposed in the liquid supply line 72. The flow controller 73 may be made up of, for example, a single opening/closing valve, or may be made up of a combination of an opening/closing valve, a flow rate control valve, a flowmeter, etc.

In general, low-DO DIW (e.g., less than 5 ppb) is supplied from the DIW supply source (for factory use) provided in a semiconductor device manufacturing factory. Therefore, there is usually no need to provide a dedicated low-DO-DIW supply device to realize the configuration example 1. However, in some cases, a low-DO-DIW supply device dedicated to the substrate processing system 1 may be provided.

A DO sensor 75, which detects a DO value of DIW stored in the inner tank 411A, is provided in the inner tank 411A of the immersion tank 441.

A drain line 76 is connected to the bottom inside the outer tank 411B of the immersion tank 441. The drain line 76 is connected to a factory waste liquid system. A plurality of drain lines 76 may be provided at different places in the outer tank 411B.

The operation of the configuration example 1 will be described. A plurality of (e.g., 25) substrates W, which has been subjected to the last batch processing (e.g., a rinsing processing after a chemical processing), is carried into the standby unit 44 by the second substrate conveyance robot 41 from the batch processing unit 42 which has performed last processing on the above substrates W. Then, the substrates W are collectively put into the immersion tank 441 (the inner tank 441A). Thereafter, the substrates W are carried out of the inner tank 441A one by one by the third substrate conveyance robot 51. When DIW is left to remain in the inner tank 441A, oxygen in the air around the inner tank 441A dissolves into the DIW, thereby gradually increasing the DO value of the DIW over time.

In order to prevent a DO value from exceeding a predetermined threshold, and to suppress a consumption amount of DIW, for example, a feedback control is performed under the control of the control device 100 (see, e.g., FIG. 1). Here, the threshold of the DO value is a DO value by which among substrates W collectively put into the immersion tank 441 (e.g., the inner tank 441A), a substrate W finally taken out from the inner tank 441A may not be subjected to problematic oxidization, for example, 100 ppb. The threshold may be reduced/increased when, for example, the longest residence time of the substrate W within the inner tank 441A is prolonged/shortened.

The feedback control may be performed by controlling the supplying of low-DO DIW into the immersion tank 441 (e.g., the inner tank 441A) from the DIW supply source 71 via the liquid supply nozzle 74, on the basis of a deviation between a DO value (measured value) detected by the DO sensor 75, and a target DO value, for example, 100 ppb herein. During normal operation, since the inner tank 441A is filled with DIW, the same amount of DIW as low-DO DIW supplied from the liquid supply nozzle 74 overflows from the inner tank 441A to the outer tank 441B. Accordingly, here, a part of DIW having a relatively high DO is replaced by DIW with a relatively low DO (for example, less than 5 ppb). This may reduce DO of DIW in the inner tank 441A. As the supply flow rate of the low-DO DIW is increased, the DO of the DIW within the inner tank 441A may be rapidly reduced.

The feedback control may be, for example, proportional-integrated-derivative (PID) control. In this case, the control of the flow rate of low-DO DIW supplied into the immersion tank 441 (e.g., the inner tank 441A) may be performed by duty control of the opening/closing valve provided for the flow controller 73. When the flow controller 73 includes the flow rate control valve whose opening degree is infinitely variable, the control of the supply flow rate of low-DO DIW may also be performed by controlling the opening degree of the flow rate control valve under PID control.

The feedback control may be, for example, HIGH/LOW control (e.g., a binary control). In this case, when the DO value (e.g., a measured value) detected by the DO sensor 75 is lower than the predetermined threshold (e.g., 100 ppb), low-DO DIW is supplied to the immersion tank 441 (e.g., the inner tank 441A) at a predetermined low flow rate (LOW) (e.g., about 1 to 2 L/min). Then, when the DO value (e.g., a measured value) is about to exceed the predetermined threshold as oxygen dissolves in DIW, low-DO DIW is supplied to the immersion tank 441 at a high flow rate (HIGH) (e.g., 30 L/min or more). The supply of DIW at a high flow rate (HIGH) may be performed for a predetermined time determined by preliminary experiments. Alternatively, the supply of DIW at a high flow rate (HIGH) may be performed until the DO value (e.g., a measured value) detected by the DO sensor 75 decreases to a predetermined value (e.g., about 50 ppb).

Before the substrate W is placed into the immersion tank 441 (the inner tank 441A), if DIW in the inner tank 441A is left to remain, DO gradually increases over time. In order to reduce DO from an excessively high state (e.g., about 10,000 ppb) to the above threshold (e.g., 100 ppb), while the required time may depend from the capacity of the inner tank 441A, the required time may be nearly 10 min in some cases.

Therefore, even during a standby state (e.g., a state where no substrate W is placed in the immersion tank 441), DO may be suppressed to, for example, about 5,000 ppb by supplying low-DO DIW to the immersion tank 441 (e.g., the inner tank 441A) at a small flow rate (e.g., about 1 to 2 L/min). Then, while the required time may depend from the capacity of the inner tank 441A, it is sufficient that the time required to reduce DO to the above threshold (e.g., 100 ppb) is only about 2 to 4 min when the supply flow rate of low-DO DIW is about 40 to 80 L/min. This may further suppress the oxidation damage of the substrate W.

When the above HIGH/LOW control (e.g., a binary control) is performed during the feedback control, low-DO DIW may be supplied at a low flow rate (LOW) in all time zones including a time zone placed in a standby state during which low-DO DIW is not being supplied at a high flow rate (HIGH).

The above feedback control may be started after the substrate W is put into the immersion tank 441 (e.g., the inner tank 441A), or may be started before the substrate W is put into the inner tank 441A. In the former case, the consumption amount of low-DO DIW may be reduced. In the latter case, oxidation damage of the substrate W may be further suppressed. Even when the substrate W is immersed in DIW having a DO of, for example, about 5,000 ppb for about a few minutes, in many cases, no problematic oxidation occurs. Therefore, it is thought that there is no problem even if the feedback control is started after the substrate W is put into the immersion tank 441 (e.g., the inner tank 441A).

In the configuration example of FIG. 11, low-DO DIW is supplied to the inner tank 441A, and then DIW in the inner tank 441A is caused to overflow into the outer tank 441B. Since oxygen dissolves in the DIW at the portion of the liquid surface of DIW stored in the inner tank 441A, an overflow method in which DIW near the liquid surface flows out to the outer tank 441B may be adopted from the viewpoint of DO reduction.

However, the method of discharging DIW within the immersion tank 441 (the inner tank 441A) is not limited to the overflow method. This may be implemented by any means, as long as relatively high-DO DIW in the inner tank 441A is replaced with relatively low-DO DIW. For example, a drain line may be connected to the immersion tank 441 (e.g., the inner tank 441A), and DIW may be discharged from the drain line. Further, when the circulation line 444 as illustrated in FIG. 2 is connected to the immersion tank 441, a drain line may be connected in the middle of the circulation line, and DIW may be discharged from the drain line.

As illustrated in FIG. 2, dissolution of oxygen in DIW is promoted when DIW overflowing from the inner tank 441A of the immersion tank 441 to the outer tank 441B is circulated back to the inner tank 441A via the circulation line 444. Therefore, adopting such a configuration is not desirable when only dissolved oxygen reduction is taken into consideration. Meanwhile, when the DIW circulation processing is performed, for example, a DIW temperature control and a DIW filtering (e.g., removal of particles) may be easily performed. Thus, if the DIW temperature control or DIW filtering is regarded as important, the DIW circulation processing may also be performed.

It is already known that the growth of an oxide film is not recognized for more than 1,000 minutes when bare silicon is immersed in DIW with a DO of 40 ppb. Then, it may be expected that the suppression of silicon oxidation may be achieved by applying the configuration example 1. Even when DO was suppressed to 100 ppb by the above feedback control, there was no problematic growth of an oxide film. By controlling DO by the above feedback control, it is possible to suppress silicon oxidation while suppressing consumption of low-DO DIW.

### Configuration Example 2

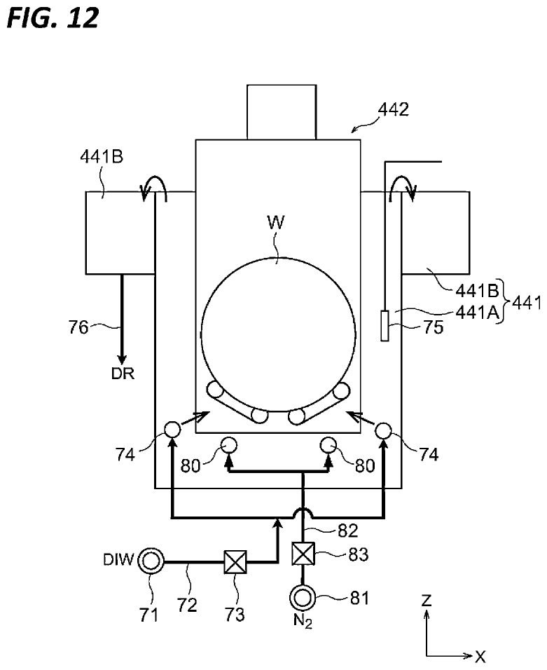

Descriptions will be made on a configuration example 1 of the standby unit 44 and the immersion tank 441 with reference to FIG. 12. In FIG. 12, members which are the same as components illustrated in FIG. 11 are given the same reference numerals. In the configuration of FIG. 12, in addition to the configuration of FIG. 11, one or more (two in the illustrated example) bubbling nozzles 80 are provided at the bottom of the immersion tank 441 (e.g., the inner tank 441A). The bubbling nozzle 80 may be formed by for example, a pipe in which a large number of gas discharge ports are provided along the arrangement direction of the substrates W. For example, N₂ gas is supplied to the bubbling nozzles 80 via a gas supply line 82 from a nitrogen (N₂) gas supply source 81 provided for factory use. A flow controller 83 is interposed in the gas supply line 82. The flow controller 83 may be made up of, for example, a single opening/closing valve, or may be made up of a combination of an opening/closing valve, a flow rate control valve, a flowmeter, etc.

Nitrogen (N₂) gas is discharged from the bubbling nozzles 80 so that microbubbles derived from N₂ gas gradually rise while being substantially evenly distributed in DIW within the inner tank 441A. By performing bubbling with N₂ gas, dissolved oxygen is expelled from DIW, and as a result, the DO value of DIW may be reduced.

The N₂ gas bubbling may be continuously performed at least while the substrate W is accommodated in the immersion tank 441 (e.g., the inner tank 441A). The N₂ gas bubbling may be started before the substrate W is put into the immersion tank 441.

In the configuration example 2 illustrated in FIG. 12, a configuration for N₂ gas bubbling is added to the configuration example 1, thereby more efficiently reducing dissolved oxygen in DIW. In this case, the feedback control of the DO value may be performed only by the control of the supply amount (e.g., an overflowing amount) of low-DO DIW, and then N₂ gas bubbling may be continuously performed under predetermined conditions while the substrate W is accommodated in the immersion tank 441 (e.g., the inner tank 441A). In order to adjust the DO value, the conditions for N₂ gas bubbling (e.g., the discharge amount of N₂ gas) may be changed on the basis of the value detected by the DO sensor 75.

It is also possible to control the DO value only by N₂ gas bubbling. In this case, for example, the conditions for N₂ gas bubbling (e.g., the flow rate of N₂ gas) may be controlled on the basis of the value detected by the DO sensor 75 so as to obtain a desired DO value. Further, in this case, in order to prevent DIW from remaining in the immersion tank 441 (e.g., the inner tank 441A), DIW may be continuously supplied from the liquid supply nozzle 74, for example, at a relatively small flow rate.

An experiment was performed, in which after N₂ gas bubbling was performed on DIW stored in the immersion tank 441, a change in DO was confirmed. Meanwhile, this was performed by using an immersion tank provided with the circulation line 444 described in FIG. 2, and the immersion tank was not as described in FIG. 12. That is, N₂ bubbling was performed while DIW was constantly overflowing from the inner tank 441A to the outer tank 441B, and DIW was allowed to circulate through a circulation line. The DO of DIW was about 7,000 ppb before the start of N₂ gas bubbling whereas the DO decreased to about 1,000 ppb when N₂ bubbling was performed for about 20 min. After that, even when N₂ bubbling was continued, there was almost no change in DO. In this experiment, it was possible to reduce DO to only about 1,000 ppb. The inventor believes that this is because a relatively large amount of oxygen dissolved in DIW during overflowing from the inner tank to the outer tank. Therefore, the inventor believes that if the overflowing DIW is not returned to the immersion tank, it is possible to greatly reduce the DO value after N₂ bubbling.

### Configuration Example 3

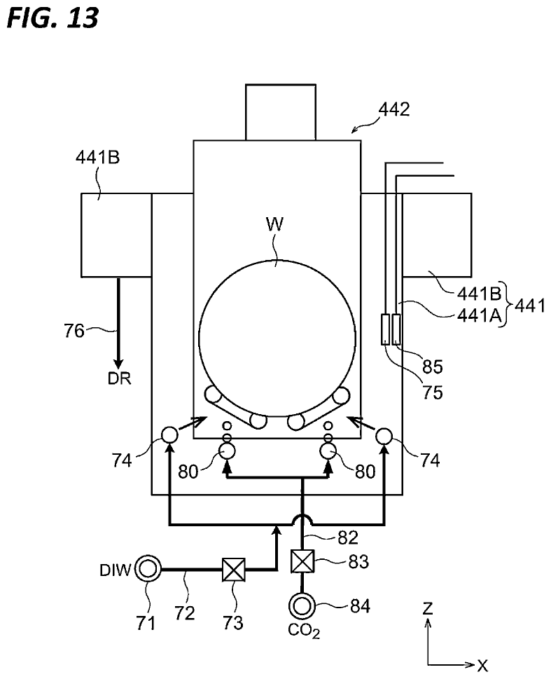

Descriptions will be made on a configuration example 3 of the standby unit 44 and the immersion tank 441 with reference to FIG. 13. In FIG. 13, members which are the same as components illustrated in FIG. 11 and FIG. 12 are given the same reference numerals. In the configuration example 3, the bubbling nozzles 80 are connected to a CO₂ supply source 84, and carbon dioxide (CO₂) gas is discharged from the bubbling nozzles 80. By performing a CO₂ gas bubbling, dissolved oxygen is expelled from DIW, thereby lowering DO.

Furthermore, when CO₂ gas bubbling is performed, not only does oxidation hardly occur due to a decrease in DO, but also corrosion of a metal film (e.g., a tungsten (W) film) may be suppressed due to a decrease in pH of DIW. In this case, in addition to the DO sensor 75, an electrical conductivity meter 85 that measures the electrical conductivity of DIW in the immersion tank 441 (e.g., the inner tank 441A) may be provided. Then, on the basis of the value detected by the electrical conductivity meter 85, conditions for CO₂ gas bubbling (e.g., the discharge amount of CO₂ gas) may be controlled so as to obtain a desired electrical conductivity (e.g., 1 μS/cm or more). In the case of CO₂ water obtained by dissolving CO₂ gas in DIW, since there is a one-to-one correspondence between pH and electrical conductivity, the management of pH (e.g., the amount of dissolved CO₂) may be performed by the electrical conductivity meter 85.

The CO₂ gas bubbling may continuously be performed at least while the substrate W is accommodated in the immersion tank 441 (e.g., the inner tank 441A). The CO₂ gas bubbling may be started before the substrate W is put into the immersion tank 441.

While the CO₂ gas bubbling is being performed, the supply of low-DO DIW from the liquid supply nozzle 74 may be performed at the same time. Meanwhile, when pH adjustment function with the CO₂ gas bubbling is emphasized, the DIW may be supplied at a small flow rate. If the CO₂ gas bubbling is performed for the purpose of removal of dissolved oxygen in DIW, the supply flow rate of DIW is optional. In this case, the control of DO of DIW within the immersion tank 441 (e.g., the inner tank 441A) may be mainly performed by supplying low-DO DIW from the liquid supply nozzle 74, and the CO₂ gas bubbling may be subsidiarily performed.

It is also possible to control the DO value or the electrical conductivity only by the CO₂ gas bubbling. In this case, for example, the conditions for the CO₂ gas bubbling (e.g., the discharge amount of CO₂ gas) may be controlled on the basis of the value detected by the DO sensor 75 or the value detected by the electrical conductivity meter 85 so as to obtain a desired DO value or a desired electrical conductivity. As the amount of CO₂ gas dissolved in DIW increases, both the DO value and the electrical conductivity are decreased, and then there is a positive correlation between the DO value and the electrical conductivity. Thus, the conditions for CO₂ gas bubbling may be controlled on the basis of only one of the DO value and the electrical conductivity. Meanwhile, in this case, the other of the DO value and the electrical conductivity may be monitored. Further, in this case as well, the DIW may not remain in the immersion tank 441 (e.g., the inner tank 441A). Thus, the DIW may be continuously supplied from the liquid supply nozzle 74 at, for example, a small flow rate.

The CO₂ bubbling may not be performed within the immersion tank 441 (e.g., the inner tank 441A). Instead, CO₂ water may be generated outside the inner tank 441A, and may be supplied into the inner tank 441A via the liquid supply line 72 and the liquid supply nozzle 74. A known CO₂ water production device may be used to produce CO₂ water outside the inner tank 441A. Alternatively, through a hollow fiber membrane module provided in the liquid supply line 72, CO₂ may be dissolved in the DIW supplied from the DIW supply source, and may be supplied into the inner tank 441A.

If CO₂ water is left while stored in the immersion tank 441 (e.g., the inner tank 441A), since CO₂ is gradually released into the air around the inner tank 441A, the CO₂ concentration of the CO₂ water is decreased. In the case of the supplying of CO₂ water from the outside of the inner tank 441A, in order to maintain the CO₂ concentration of CO₂ water stored in the immersion tank 441, within a desired range, new CO₂ water may be supplied into the inner tank 441A from the liquid supply nozzle 74, and then the CO₂ water of the inner tank 441A may be discharged to the outer tank 441B by overflowing. The supply amount of new CO₂ water may be adjusted by feedback control, on the basis of a deviation between a value detected by the electrical conductivity meter 85 and a target value (e.g., 0.5 MΩ·cm). The feedback control may be performed by the PID control, or HIGH/LOW control (binary control) in the same manner as described in the configuration example 1.

### Configuration Example 4

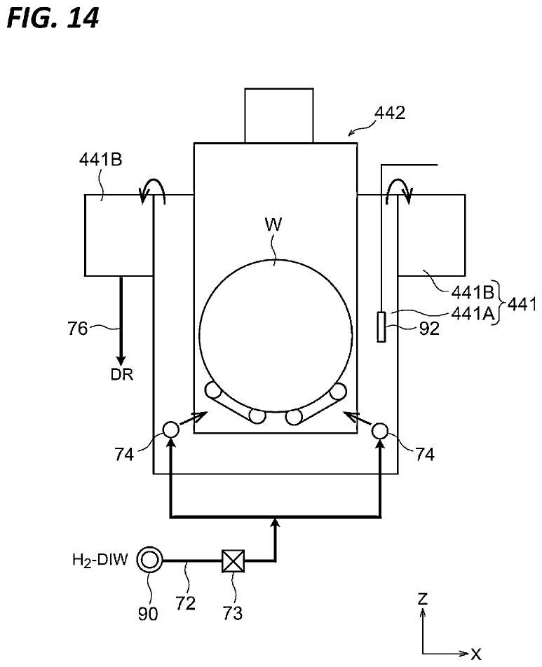

Descriptions will be made on a configuration example 4 of the standby unit 44 and the immersion tank 441 with reference to FIG. 14. In FIG. 14, members which are the same as components illustrated in FIG. 11 are given the same reference numerals and descriptions as provided above. In the configuration example 4, hydrogen water (H₂-DIW) is supplied to the liquid supply nozzle 74 from a hydrogen water supply source 90 via the liquid supply line 72. An oxidation reduction potential (ORP) sensor 92 for measuring the ORP of hydrogen water (H₂ water) is provided inside the immersion tank 441 (e.g., the inner tank 441A). As for the hydrogen water supply source 90, a known and commercially available hydrogen water supply device may be used. For example, the hydrogen water supply source 90 provided for factory use may be used.

The hydrogen water supplied from the hydrogen water supply source 90 may be obtained by dissolving hydrogen in DIW at a concentration of about 1 to 2 ppm. The oxidation-reduction potential of deionized water is about +700 mV whereas the oxidation-reduction potential of hydrogen water having a hydrogen concentration of about 1 to 2 ppm is about −200 mV to −300 mV. By lowering the oxidation-reduction potential in this manner, it is possible to suppress oxidation, and to suppress corrosion of a metal film (e.g., a tungsten (W) film). Since DO is also decreased through a hydrogen water production process, an oxidation may be further suppressed.

If hydrogen water is left while stored in the immersion tank 441 (the inner tank 441A), since hydrogen is gradually released into the air around the immersion tank 441, the hydrogen concentration in the hydrogen water is decreased. In order to maintain the hydrogen concentration of hydrogen water stored in the immersion tank 441, within a desired range, new hydrogen water may be supplied into the inner tank 441A from the liquid supply nozzle 74, and then the hydrogen water of the inner tank 441A may be discharged to the outer tank 441B by overflowing. The supply amount of new hydrogen water may be adjusted by feedback control on the basis of a deviation between a value detected by the ORP sensor 92 and a target value (e.g., −200 mV). The feedback control may be performed by PID control, or HIGH/LOW control (e.g., a binary control) in the same manner as described in the configuration example 1.

Hereinafter, descriptions will be made on an experiment conducted to confirm the effect of CO₂ water and hydrogen water. A bare silicon wafer was sequentially subjected to the following steps while being held and rotated by the above wafer spin chuck.
(1) cleaning processing with DHF (e.g., HF:DIW=1:100): 25° C., 60 sec
(2) rinsing with CO₂ water: 30 sec
(3) spin drying: 40 sec
(4) various test solutions (e.g., supply of CO₂ water, hydrogen water, and DIW (e.g., 27° C., DO: about 5 ppb)): 60 sec
(5) spin drying: 40 sec

After the completion of the step (3) and the step (5), the film thickness of the oxide film was measured by using a spectroscopic ellipsometer.

The film thickness of the oxide film was 2.669 Å immediately after the completion of the step (3).

When CO₂ water was used in the step (4), the film thickness of the oxide film was 2.608 Å after the completion of the step (5).

When hydrogen water was used in the step (4), the film thickness of the oxide film was 3.263 Å after the completion of the step (5).

When DIW was used in the step (4), the film thickness of the oxide film was 4.201 Å after the completion of the step (5).

From the above, it can be found that an inhibitory effect of the growth of the natural oxide film is higher in the immersion in CO₂ water and hydrogen water, than in the case of the immersion in DIW.

Even when the above configuration examples 1 to 4 are applied, a hydrophilization processing liquid or a zeta potential negative processing liquid may be supplied to the substrate W taken out from the immersion tank 441 by using the spray nozzle 447 (see, e.g., FIG. 2 and FIG. 3).

The above configuration examples 1 to 4 are useful for the substrate W in which a material (e.g., silicon (Si), etc.) having an oxidation problem and/or a material (e.g., tungsten (W), molybdenum (Mo), ruthenium (Ru), etc.) having a dissolution (e.g., a metal loss) problem are exposed on the surface (e.g., including a surface within a pattern recess), after a series of processes are completed in the batch processing section.

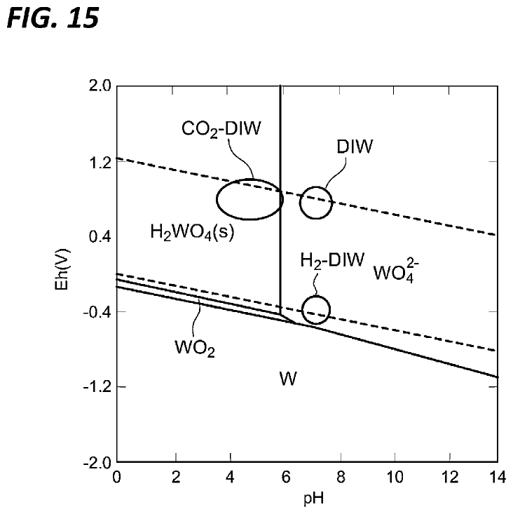

The reason metal loss is less likely to occur in tungsten due to CO₂ water and hydrogen water is briefly described by using a Pourbaix diagram of FIG. 15. Further, as may be seen from the previously described tungsten dissolution mechanism, the environment may be such that WO₄²⁻ (ionic state) is not easily formed. In CO₂ water, the combination of the oxidation-reduction potential (the vertical axis in the pourbaix diagram) and pH is in a region where H₂WO₄² is stable. Thus, both DIW and hydrogen water (H₂-DIW) have a region where WO₄²⁻ is stable. However, since the oxidation-reduction potential of hydrogen water is lower than that of DIW, elution of tungsten hardly occurs.

The embodiments disclosed herein should be considered to be illustrative in all aspects and not restrictive. Regarding the embodiments, omission, replacement, or modification may be made in various forms without departing from the scope of the appended claims and its spirit.

The substrate is not limited to a semiconductor wafer, and may be any other type of substrate used in the manufacturing of semiconductor devices, such as a glass substrate or a ceramic substrate.

### DESCRIPTION OF SYMBOLS

W Substrate
4 Batch processing section
42 Batch processing unit
44 Standby section (standby unit)
441 Immersion tank
51, 63 Conveyance system
51 First substrate conveyance unit (Third substrate conveyance robot)
6 Single-wafer processing section
61, 62 Single-wafer processing unit

1. A substrate processing apparatus comprising:
a batch processing section including a plurality of batch processing units each provided with a processing tank that stores a processing liquid, and configured to immerse a plurality of substrates in the processing liquid stored within the processing tank and collectively perform a liquid processing on the plurality of substrates;
a single-wafer processing section including a single-wafer processing unit that processes the plurality of substrates processed in the batch processing section, one by one;
a standby section including an immersion tank that stores an immersion liquid, and configured to stand by the plurality of substrates processed by the batch processing section, while being immersed in the immersion liquid; and
a conveyance system configured to convey the plurality of substrates from the standby section to the single-wafer processing section, and including a first substrate conveyance unit that takes out the plurality of substrates immersed in the immersion liquid within the immersion tank one by one from the immersion liquid,
wherein the standby section is configured to perform at least one of a first liquid processing and a second liquid processing on the substrates,
the first liquid processing hydrophilizes surfaces of the substrates, or improves or maintains hydrophilicity of the surfaces of the substrates, and
the second liquid processing makes a zeta potential of the surfaces of the substrates negative.

2. A substrate processing apparatus comprising:
a batch processing section including a plurality of batch processing units each provided with a processing tank that stores a processing liquid, and configured to immerse a plurality of substrates in the processing liquid stored within the processing tank and collectively perform a liquid processing on the plurality of substrates;
a single-wafer processing section including a single-wafer processing unit that processes the plurality of substrates processed in the batch processing section, one by one;
a standby section including an immersion tank that stores an immersion liquid, and configured to stand by the plurality of substrates processed by the batch processing section, while being immersed in the immersion liquid; and
a conveyance system configured to convey the plurality of substrates from the standby section to the single-wafer processing section, and including a first substrate conveyance unit that takes out the plurality of substrates immersed in the immersion liquid within the immersion tank one by one from the immersion liquid,
wherein the standby section is configured to perform at least one of a first immersion processing and a second immersion processing on the substrates,
the first immersion processing immerses the substrates in water as the immersion liquid stored in the immersion tank, the water being controlled to have a dissolved oxygen concentration of a predetermined value or less, and
the second immersion processing immerses the substrates in hydrogen water or CO₂ water as the immersion liquid stored in the immersion tank.

3. The substrate processing apparatus according to claim 1, wherein the standby section is configured to perform both the first liquid processing and the second liquid processing,
the first liquid processing is performed by immersing the plurality of substrates in a first processing liquid as the immersion liquid stored within the immersion tank, and the first processing liquid is a liquid capable of hydrophilizing the surfaces of the plurality of substrates, or improving or maintaining hydrophilicity of the plurality of surfaces of the substrates, and
the standby section further includes a processing liquid nozzle, and the second liquid processing is performed by supplying a second processing liquid from the processing liquid nozzle to the plurality of substrates, the second processing liquid being capable of making the zeta potential of the surfaces of the plurality of substrates negative, while or immediately after the plurality of substrates are taken out from the immersion liquid by the first substrate conveyance unit.

4. The substrate processing apparatus according to claim 1, wherein the standby section is configured to perform the first liquid processing, and
the first liquid processing is performed by immersing the plurality of substrates in a first processing liquid as the immersion liquid stored within the immersion tank, and the first processing liquid is a liquid capable of hydrophilizing the surfaces of the plurality of substrates, or improving or maintaining hydrophilicity of the surfaces of the plurality of substrates.

5. The substrate processing apparatus according to claim 1, wherein the standby section is configured to perform the second liquid processing, and
the second liquid processing is performed by immersing the plurality of substrates in a second processing liquid as the immersion liquid stored within the immersion tank, and the second processing liquid is a liquid capable of making the zeta potential of the surfaces of the plurality of substrates negative.

6. The substrate processing apparatus according to claim 1, wherein the standby section is configured to perform the second liquid processing,
the immersion tank stores deionized water, and
the standby section further includes a processing liquid nozzle, the second liquid processing is performed by supplying a second processing liquid from the processing liquid nozzle to the plurality of substrates, and the second processing liquid is capable of making the zeta potential of the plurality of surfaces of the substrates negative, while or immediately after being taken out from the immersion liquid by the first substrate conveyance unit.

7. The substrate processing apparatus according to claim 3, wherein the first processing liquid is ozonated water, SC₂, SPM or a hydrogen peroxide solution.

8. The substrate processing apparatus according to claim 3, wherein the second processing liquid is an alkaline liquid.

9. The substrate processing apparatus according to claim 8, wherein the alkaline liquid is ammonia-containing functional water, tetramethylammonium hydroxide (TMAH), or an organic alkaline solution.

10. The substrate processing apparatus according to claim 3, wherein the second processing liquid is an anionic surfactant.

11. The substrate processing apparatus according to claim 2, wherein the standby section is configured to perform the first immersion processing, and
the first immersion processing is performed by immersing the plurality of substrates in deionized water that is stored in the immersion tank and has a dissolved oxygen concentration of 100 ppb or less.

12. The substrate processing apparatus according to claim 11, wherein the standby section includes a bubbling nozzle that discharges gas in a form of bubbles to remove dissolved oxygen in the deionized water stored in the immersion tank.

13. The substrate processing apparatus according to claim 12, further comprising:
a dissolved oxygen concentration sensor configured to measure the dissolved oxygen concentration in the deionized water stored within the immersion tank; and
a controller configured to control an operation of gas discharge from the bubbling nozzle such that the dissolved oxygen concentration of the deionized water stored within the immersion tank is maintained at 100 ppb or less.

14. The substrate processing apparatus according to claim 11, wherein the standby section includes a low-dissolved oxygen concentration deionized water supply device that supplies low-dissolved oxygen concentration deionized water, as deionized water having a dissolved oxygen concentration lower than 100 ppb, into the deionized water stored within the immersion tank, so that a part of the deionized water stored within the immersion tank is replaced with the supplied low-dissolved oxygen concentration deionized water.

15. The substrate processing apparatus according to claim 14, further comprising:
a dissolved oxygen concentration sensor configured to measure the dissolved oxygen concentration in the deionized water stored within the immersion tank; and
a controller configured to control supplying of the low-dissolved oxygen concentration deionized water into the immersion tank such that the dissolved oxygen concentration of the deionized water stored within the immersion tank is maintained at 100 ppb or less.

16. The substrate processing apparatus according to claim 2, wherein the standby section is configured to perform the second immersion processing, and
the second immersion processing is performed by immersing the plurality of substrates in CO₂ water or hydrogen water stored within the immersion tank, the CO₂ water having an electrical conductivity of less than 1 MΩ·cm, and the hydrogen water having a dissolved hydrogen concentration of more than 1 ppm.

17. The substrate processing apparatus according to claim 1, wherein the conveyance system further includes a substrate transfer unit that temporarily holds a substrate taken out from the immersion liquid by the first substrate conveyance unit, and a second substrate conveyance unit that takes out the substrate from the substrate transfer unit and conveys the substrate to the single-wafer processing section, and
the substrate transfer unit includes a stage on which the substrate is placed in a horizontal posture, and a coating liquid nozzle that supplies a coating liquid to the substrate placed on the stage to maintain a state where at least a surface of the substrate is covered with a liquid.

18. The substrate processing apparatus according to claim 17, wherein the first substrate conveyance unit takes out the substrate immersed in a vertical posture in the immersion liquid within the immersion tank, in the vertical posture, from the immersion liquid, performs a conversion into a horizontal posture, and carries the substrate in the horizontal posture into the substrate transfer unit, and
the second substrate conveyance unit carries the substrate placed on the stage of the substrate transfer unit in the horizontal posture, into the single-wafer processing unit of the single-wafer processing section while the horizontal posture is maintained.

19. The substrate processing apparatus according to claim 3, further comprising:
a circulation path connected to the immersion tank of the standby section, and a pump and a temperature controller interposed in the circulation path,
wherein the immersion liquid stored within the immersion tank is temperature-controlled while circulating through the circulation path.

20. A substrate processing method comprising:
providing a substrate processing apparatus including:
a batch processing section including a plurality of batch processing units each provided with a processing tank that stores a processing liquid, and configured to immerse a plurality of substrates in the processing liquid stored within the processing tank and collectively perform a liquid processing on the plurality of substrates;
a single-wafer processing section including a single-wafer processing unit that processes the plurality of substrates processed in the batch processing section, one by one;
a standby section including an immersion tank that stores an immersion liquid, and configured to stand by the plurality of substrates processed by the batch processing section, while being immersed in the immersion liquid; and
a conveyance system configured to convey the plurality of substrates from the standby section to the single-wafer processing section, and including a first substrate conveyance unit that takes out the plurality of substrates immersed in the immersion liquid within the immersion tank one by one from the immersion liquid; and
in the standby section, performing, on the plurality of substrates, at least one of:
a first liquid processing that hydrophilizes surfaces of the plurality of substrates or a liquid processing that improves or maintains hydrophilicity of the surfaces of the plurality of substrates, and
a second liquid processing that makes a zeta potential of the surfaces of the plurality of substrates negative.

21. A substrate processing method comprising:
providing a substrate processing apparatus including:
a batch processing section including a plurality of batch processing units each provided with a processing tank that stores a processing liquid, and configured to immerse a plurality of substrates in the processing liquid stored within the processing tank and collectively perform a liquid processing on the plurality of substrates;
a single-wafer processing section including a single-wafer processing unit that processes the plurality of substrates processed in the batch processing section, one by one;
a standby section including an immersion tank that stores an immersion liquid, and configured to stand by the plurality of substrates processed by the batch processing section, while being immersed in the immersion liquid; and
a conveyance system configured to convey the plurality of substrates from the standby section to the single-wafer processing section, and including a first substrate conveyance unit that takes out the plurality of substrates immersed in the immersion liquid within the immersion tank one by one from the immersion liquid; and
in the standby section, performing, on the plurality of substrates, at least one of:
a first immersion processing of immersing the plurality of substrates in water as the immersion liquid, the water being controlled to have a dissolved oxygen concentration of a predetermined value or less, and
a second immersion processing of immersing the plurality of substrates in hydrogen water or CO₂ water as the immersion liquid.

22. The substrate processing method according to claim 20, wherein both the first liquid processing and the second liquid processing are performed in the standby section,
the first liquid processing is performed by immersing the plurality of substrates in a first processing liquid stored within the immersion tank, the first processing liquid being capable of hydrophilizing the surfaces of the plurality of substrates, or improving or maintaining hydrophilicity of the surfaces of the plurality of substrates, and
the second liquid processing is performed by discharging a second processing liquid toward the substrates from a processing liquid nozzle provided in the standby section, the second processing liquid being capable of making the zeta potential of the surfaces of the plurality of substrates negative while or immediately after being taken out from the immersion liquid by the first substrate conveyance unit.

23. The substrate processing method according to claim 20, wherein the first liquid processing is performed in the standby section, and
the first liquid processing is performed by immersing the plurality of substrates in a first processing liquid stored within the immersion tank, the first processing liquid being capable of hydrophilizing the surfaces of the plurality of substrates or improving or maintaining hydrophilicity of the surfaces of the plurality of substrates.

24. The substrate processing method according to claim 20, wherein the second liquid processing is performed in the standby section, and
the second liquid processing is performed by immersing the plurality of substrates in a second processing liquid stored within the immersion tank, the second processing liquid being capable of making the zeta potential of the surfaces of the plurality of substrates negative.

25. The substrate processing method according to claim 20, wherein the second liquid processing is performed in the standby section,
the immersion tank stores deionized water as the immersion liquid, and
the second liquid processing is performed by supplying a second processing liquid to the plurality of substrates from a processing liquid nozzle provided in the standby section, the second processing liquid being capable of making the zeta potential of the surfaces of the plurality of substrates negative while or immediately after being taken out from the immersion liquid by the first substrate conveyance unit.

26. The substrate processing method according to claim 21, wherein the first immersion processing is performed in the standby section, and
the first immersion processing is performed by immersing the plurality of substrates in deionized water that is stored within the immersion tank and has a dissolved oxygen concentration of 100 ppb or less.

27. The substrate processing method according to claim 26, wherein in order to reduce the dissolved oxygen concentration of the deionized water stored within the immersion tank to 100 ppb or less,
the first immersion processing is performed by at least one of:
removing dissolved oxygen in the deionized water through bubbling with nitrogen gas, hydrogen gas, or carbon dioxide gas, and
supplying low-dissolved oxygen concentration deionized water, as deionized water having a dissolved oxygen concentration lower than 100 ppb, to the deionized water stored within the immersion tank, and replacing a part of the deionized water stored within the immersion tank with the supplied low-dissolved oxygen concentration deionized water.

28. The substrate processing method according to claim 21, wherein the second immersion processing is performed in the standby section, and
the second immersion processing is performed by immersing the plurality of substrates in CO₂ water or hydrogen water stored within the immersion tank, the CO₂ water having an electrical conductivity of less than 1 MΩ·cm, and the hydrogen water having a dissolved hydrogen concentration of more than 1 ppm.
